(19) United States
(12) Patent Application Publication
(10) Pub. No.: US 2024/0090353 A1
(43) Pub. Date: Mar. 14, 2024

(54) SUB-EUV PATTERNING HEATERS FOR BAR MUSHROOM CELL PCM

(71) Applicant: International Business Machines Corporation, Armonk, NY (US)

(72) Inventors: Samuel Sung Shik Choi, Ballston Lake, NY (US); Kevin W. Brew, Niskayuna, NY (US); Raghuveer Reddy Patlolla, Guilderland, NY (US)

(21) Appl. No.: 17/942,262

(22) Filed: Sep. 12, 2022

(51) Int. Cl. H01L 45/00; H01L 27/24

(52) U.S. Cl. CPC H01L 45/126; H01L 27/2463; H01L 45/06; H01L 45/16

(57) ABSTRACT

A phase change material (PCM) memory cell having a metal heater element of sub-EUV dimension. The PCM memory cell includes a bottom electrode of a metal-containing material, a memory cell structure including a phase change material; and a metal heater element of sub-extreme ultraviolet (sub-EUV) dimension situated between and electrically connecting the bottom electrode and PCM memory cell structure. The metal heater element is formed of a circular via structure of sub-EUV dimension and has a seamless metal-nitride fill material. The circular via structure of sub-extreme ultraviolet (sub-EUV) dimension further includes a metal-nitride liner of sub-EUV dimension, the metal-nitride liner of sub-EUV dimension including a thicker metal-nitride liner bottom surface portion and thinner sidewall metal-nitride portions. The thicker metal-nitride liner bottom surface portion improves heat insulation and provides for high resistance/low power switching and reduced amorphous phase change material volumes.

### BACKGROUND

The present disclosure relates to mushroom cell phase change devices, and more particularly, an integration and patterning approach to enable sub-EUV bottom electrode heaters that can be metallized for use with mushroom cell phase change devices.

Even with the advent of extreme ultra-violet (EUV) lithography enabling sub-40 nm pitch print definition, the lack of robustness of the organic materials and integration scheme, pattern transfer have suffered from mask erosion leading pattern collapse and poor line edge roughness.

In mushroom cell phase-change devices, “the mushroom size” (hence energy required for the switching) is determined by the bottom electrode (heater) area. Various sub-lithographic techniques for the definition of the heater have been proposed, including side-wall spacer approaches, use of carbon nanotubes as heaters, and formation of a nanoscale conductive filament in an oxide layer atop the heater via electrical breakdown (rupture oxide).

Limitations of EUV hinder efficient ultra-small heater dimensions and require multi-layer ALD/CVD depositions to create a thin heater filaments.

### BRIEF SUMMARY

In one aspect, there is provided an integration and semiconductor device patterning approach to enable sub-EUV bottom electrode heaters that can be metallized simply with CVD metals and metal nitrides for high resistance/low power switching and reduced amorphous volumes.

A further aspect provides for a multi-mushroom cross-bar like array enabled by sub-EUV heaters.

By minimizing the heater dimension, the amorphous switching volume of the PCM cell is minimized and the reduced contact area reduces the PCM cell programming current more effectively. This provides for undamaged GST volumes, reduces current draw (lower power), and improves device density.

In accordance with a first embodiment, there is provided a phase change material (PCM) memory cell. The PCM memory cell comprises: a bottom electrode of a metal-containing material; a memory cell structure comprising a phase change material; and a metal heater element of sub-extreme ultraviolet (sub-EUV) dimension situated between and electrically connecting the bottom electrode and PCM memory cell structure, the metal heater element comprising a circular via structure of sub-EUV dimension having a seamless fill material.

In an embodiment, the seamless fill material comprises a metal-nitride fill material.

In an embodiment, the circular via structure of sub-extreme ultraviolet (sub-EUV) dimension further comprises a metal-nitride liner of sub-EUV dimension.

In an embodiment, the metal-nitride liner of sub-EUV dimension includes a thicker metal-nitride liner bottom surface portion and thinner sidewall metal-nitride portions. The thicker metal-nitride liner bottom surface portion improves heat insulation, i.e., blocks heat better.

Further, the metal heater element comprising the circular via structure of sub-EUV dimension provides for high resistance/low power switching and reduced amorphous phase change material volumes.

In an embodiment, the metal heater element comprising a circular via structure of sub-EUV dimension includes an outer metal-nitride liner of a first metal-nitride material and an inner metal-nitride filament layer of a second metal-nitride material.

In accordance with a further embodiment, there is provided a phase change material (PCM) memory cell array. The PCM memory cell array comprises: a first insulative material layer comprising a plurality of bottom electrodes of a metal-containing material; a plurality of memory cell structures of phase change material, each memory cell structure in alignment with a respective bottom electrode; and a plurality of metal heater elements of sub-extreme ultraviolet (sub-EUV) dimension, a respective metal heater element situated between and electrically connecting a respective bottom electrode and a respective PCM memory cell structure, each respective metal heater element comprising a circular via structure of sub-EUV dimension having a seamless fill material.

In the PCM memory cell array, the seamless fill material comprises a metal-nitride fill material.

In a further embodiment, the metal heater element comprising a circular via structure of sub-extreme ultraviolet (sub-EUV) dimension further comprises a metal-nitride liner of sub-EUV dimension. The metal-nitride liner of sub-EUV dimension includes a thicker metal-nitride liner bottom surface portion and thinner sidewall metal-nitride portions. The thicker metal-nitride liner bottom surface portion improves heat insulation, i.e., blocks heat better. The metal heater element comprising the circular via structure of sub-EUV dimension provides for high resistance/low power switching and reduced amorphous phase change material volumes.

In a further embodiment, each metal heater element comprises a circular via structure of sub-EUV dimension includes an outer metal-nitride liner of a first metal-nitride material and an inner metal-nitride filament layer of a second metal-nitride material.

According to an aspect of the present disclosure, a method of forming a phase change material (PCM) memory cell is provided. The method includes an integration approach of multiple steps that include at least one tapered reactive ion etching (RIE) process for achieving an insulating layer having a topographical profile and aspect ratio that enables a metal material fill into a circular via of sub-EUV dimension with minimal or no voids/gaps/seams at the sub-EUV dimension that lends to a unique structure.

### BRIEF DESCRIPTION OF THE SEVERAL VIEWS OF THE DRAWINGS

FIGS. 1A-1G depict one embodiment of a method for manufacturing a PCM memory cell device in a manner that generates sub-EUV via features in an aspect of the present disclosure;

FIGS. 2A-2C depict an alternate embodiment of method steps for manufacturing a PCM memory device in a manner that generates sub-EUV via features according to a further aspect of the present disclosure.

FIG. 3 depicts a memory cell structure having a bottom heater electrode structure formed in accordance with the embodiments described herein;

FIGS. 4A-4C represent various views of a 2-D or 3-D PCM cell memory array including a stencil structure having sub-EUV dimensioned bottom lined heater metal structures according to an embodiment herein; and

FIGS. 5A-5C represent various views of a 2-D or 3-D PCM cell memory array of a further embodiment that includes PCM memory cells formed on a stencil structure having sub-EUV dimensioned bottom heater metal structures according to a further embodiment.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

In one embodiment, the present disclosure provides a method and structure for forming PCM memory cells on a semiconductor wafer.

In particular, there is provided an integration and patterning approach to enable sub-EUV (i.e., critical dimension <25 nm) bottom electrode heaters that can be metallized simply with CVD metals and metal nitrides for high resistance/low power switching and reduced amorphous volumes.

The disclosure is directed to a multi-mushroom cross-bar like array enabled by sub-EUV heaters and a method of manufacture. By minimizing the heater dimension, the amorphous switching volume is minimized and the reduced contact area reduces the PCM cell programming current more effectively.

The method advantageously provides undamaged GST volumes in PCM cells, reduces current draw (lower power), and improves device density.

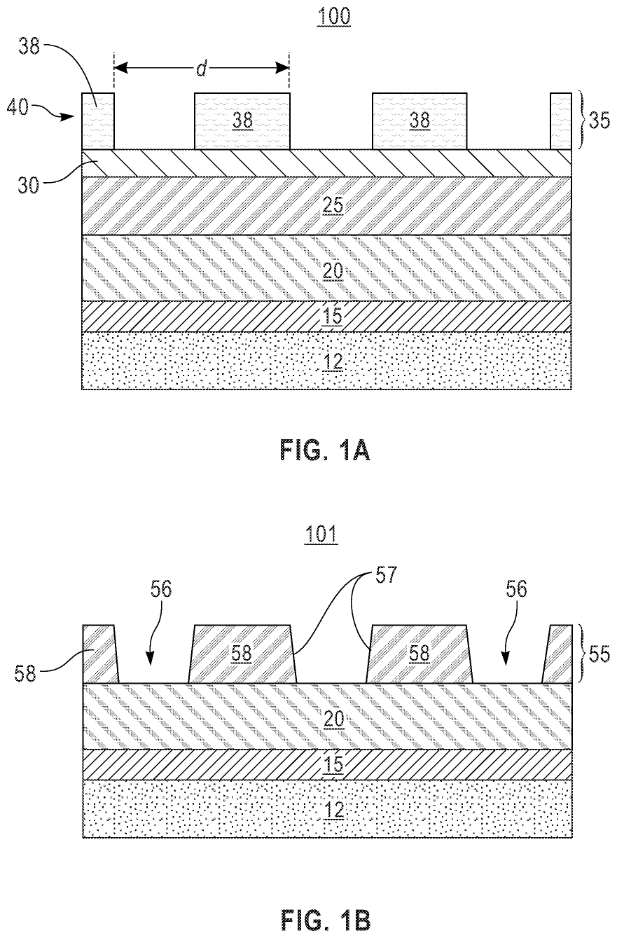

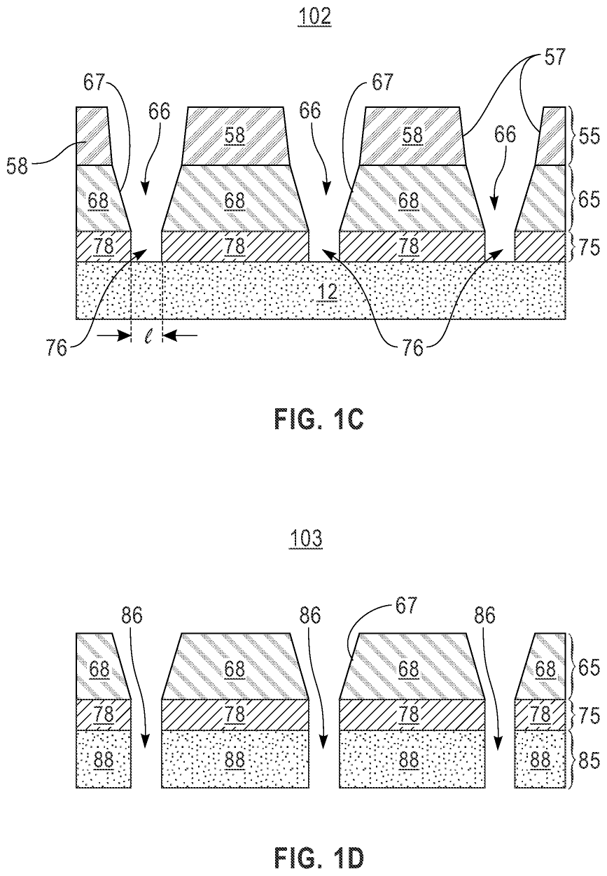

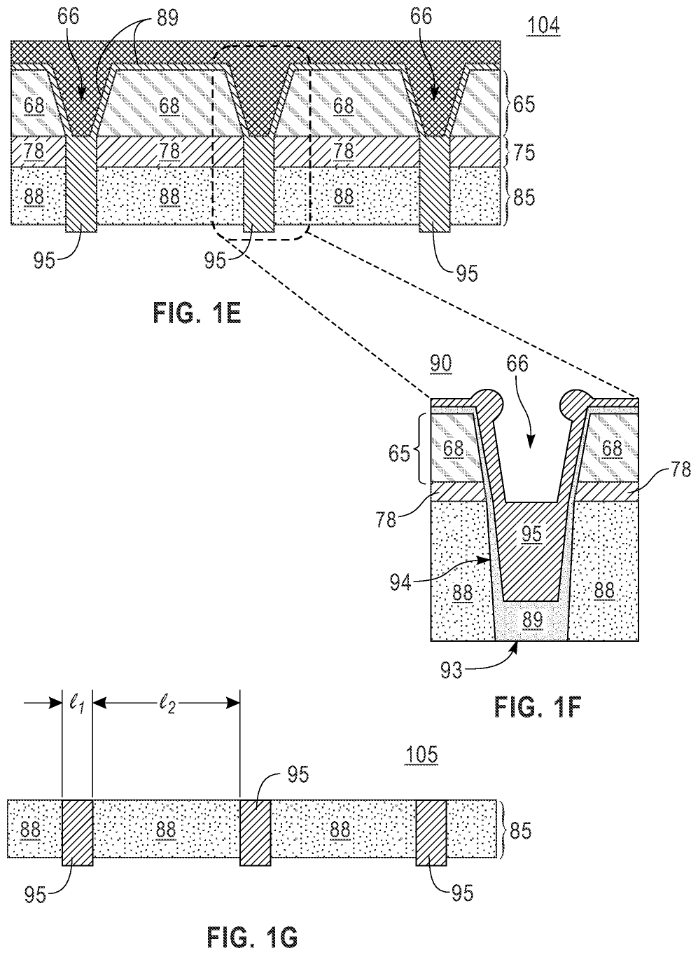

FIGS. 1A-1G depict one embodiment of a method for manufacturing a memory device in a manner that generates sub-EUV via features in an aspect of the present disclosure.

As shown in FIG. 1A, there is depicted a cross-sectional view of an initial semiconductor structure 100. Initial Structure 10 is formed after performing of MOL or BEOL semiconductor manufacturing processes for fabricating conductive wiring, contacts, insulating material layers, metal levels, etc. that interconnect already formed individual devices such as transistors, capacitors, resistors, etc. (not shown). As shown in FIG. 1A, the exemplary structure 100, includes, from bottom to top: a first inter-level dielectric layer 12 of a low-k dielectric material, e.g., SiN; an overlying dielectric material cap layer 15 formed above the inter-level dielectric material layer 12, e.g., TiN; a second inter-level dielectric material layer 20, e.g., low-k dielectric material such as an oxide dielectric material, e.g., SiO₂, or a silicon doped oxide formed above the dielectric material cap layer 15; an overlying developable OPL (organic planarization material) layer 25. In embodiments, first inter-level dielectric layer 12 of a SiN dielectric material is formed to a thickness of approximately 75 nm. The overlying TiN cap layer 15 functioning as a hard mask formed above the inter-level dielectric material layer 12 is formed to a thickness of approximately 10 nm-30 nm. The overlying second inter-level dielectric material layer 20 of SiO₂ formed above the dielectric material cap layer 15 can also be a Tetraethyl orthosilicate (TEOS) dielectric material layer formed to a thickness of approximately 100 nm-300 nm range.

Further provided on top of inter-level dielectric material layer 20 is an overlaying top anti-reflective coating layer 30 such as a Silicon-containing antireflection coating (SiARC).

Further formed on the top SiARC layer 30 is a patterned mask layer, e.g., a photoresist material layer 40, formed as a result of applied photolithographic imaging and developing process to result in a formed mask pattern 35.

That is, the initial structure 100 of FIG. 1A results from exposing a formed mask layer 40 to an image pattern (not shown) using a photo-lithography system, and thereafter in FIG. 1A, the image pattern is developed in a developing solvent to form the pattern 35 in the photo-resist layer 40. The resist pattern 35 includes a series of openings with resist structures 38 formed in a periodic pattern. In an embodiment, a periodicity computed as a distance d between adjacent resistance pattern layer structures 38 is about 32 nm-40 nm range.

FIG. 1B shows a cross-sectional view of a structure 101 resulting from transferring the pattern 35 in the photo-resist layer 40 in the structure 100 of FIG. 1A to the underlying OPL layer 25 using a dry etching process. That is, as a result of a reactive ion etching (RIE) step that is conducted selective to the surface of dielectric layer level 20, there is an etch through the SiARC layer 38 and OPL layer 25 to form a pattern 55 in the OPL layer defined by the resist structures 38 that includes a series of slightly tapered openings 56 with remaining OPL structures 58 having a periodicity commensurate with the period distance d of structures 38 the original resist layer pattern 35. In an embodiment, a tapered RIE etch is conducted so that each of the structures 58 have a slightly sloped sidewall 57. In an embodiment, the etch is conducted to formed structure 58 having a defined aspect ratio, i.e., structures 58 have edges that form a <90° degree angle, e.g., an angle ranging from between 86° degrees to 89.5° degrees with respect to a perpendicular. The resulting structure 101 of FIG. 1B depicts the result of further removing any remaining resist layer 35 and removing SiARC layer 30.

FIG. 1C shows a cross-sectional view of a structure 102 resulting from performing a first RIE etch to transfer the pattern 55 in the OPL layer 25 in the structure 101 of FIG. 1B to the underlying hard mask layer 15 using a further tapered dry etching process, and a second pattern transfer using a hard mask (HM) metal RIE through hard mask layer 15. That is, as a result of a further tapered RIE etch step that is conducted selective to the surface of hard mask layer 15, the etch through the SiO₂ layer 20 results in a formed pattern 65 of funnel shaped vias 66 in the dielectric material. e.g., SiO₂ layer 20, as defined by the overlying tapered openings 56 between OPL layer structures 58. This formed pattern 65 includes a series of funnel shaped via openings 66 leaving remaining dielectric layer structures 68 having a periodicity commensurate with the period distance d of structures 38 the original resist layer pattern 35. In an embodiment, a first tapered RIE etch is conducted so that each of the remaining dielectric layer structures 68 in pattern 65 have an increased sloped sidewall 67 relative to the slope of the sidewalls 57 of overlying structures 58 in OPL patterned layer 55. In an embodiment, a capacitively coupled plasma chamber using a polymerizing plasma chemistry of N₂/H₂ can be tuned to achieve the desired profile openings 56 in patterned layer 55. In an embodiment, a tapered etch conducted in a capacitively coupled plasma chamber using a polymerizing plasma chemistry of C₄F₈/O₂/Ar can be tuned to achieve sloped sidewall structures 68 having a defined aspect ratio, i.e., structures 68 have edges that form an angle less than (<) 90°, e.g., between 86° degrees to 89.5° degrees with respect to a perpendicular to result in the desired profile openings 66 in patterned layer 65. As shown in FIG. 1C, the formed funnel shaped via openings 66 expose top surface portions of the hard mask layer 15 between sloped sidewall structures 68 structures of a length l. In an embodiment, this exposed hard mask top surface length l is approximately 10 nm-20 nm. By using the two successive plasma RIE conditions, the initially defined critical dimension (CD) can be shrunk by 20-30 nm to define a final CD of less than 20 nm (a highly shrinking RIE process).

FIG. 1C further shows the resulting structure 102 formed after performing a further isotropic etch that is conducted selective to the bottom interlevel dielectric layer 12 to transfer dielectric material layer pattern 65 to the hard mask layer 15 using a standard hard mask metal RIE etch. This results in a hard mask layer pattern 75 having periodic vertical circular vias or openings 76 between remaining hard mask structures 78, with each vertical circular via opening 76 of a diameter length l, e.g., approximately 8 nm in diameter. The resulting hard mask structures 78 have straight edge sidewalls and are approximately 28+/−0.1 nm in length.

FIG. 1D shows a cross-sectional view of a structure 103 resulting from transferring the pattern 75 defined in the hard mask layer 15 in the structure 102 of FIG. 1C to the underlying dielectric layer 12 using a dry etching process. That is, as a result of a further RIE step and etch bias technique that is conducted through defined circular via openings 76, a final pattern 85 in the dielectric layer 12 results which pattern includes a series of vertically-oriented circular via openings 86 aligned with circular via openings 76 in the hard mask layer 15. In an embodiment, an etch bias of −10 nm (etch bias) results in a sub-EUV feature size opening 86 of about 8 nm. The resulting pattern 85 includes remaining SiN layer structures 88 having a periodicity commensurate with the period distance d of structures 38 the original resist layer pattern 35. The resulting structure 103 of FIG. 1D depicts the result of further removing any remaining overlaying OPL layer structures 58. In an embodiment, an etch bias is applied according to:

DCD(LTH)−FCD(SiN)=10 nm

where DCD represents the developed critical dimension, LTH represents the lithographic print, and FCD(ILD) represents the final critical dimension (e.g., final CD printed in the SiN or any interlevel dielectric). As an example, given a starting pitch d=36 nm, then a lithographic print CD achieved is 18 nm and the highly shrinking RIE CD shrinks further to 10 nm, and the final CD=8 nm of the openings 76 in layer 75 while maintaining the pitch of d=36 nm which is self consistent with the initial pitch.

FIG. 1E shows a cross-sectional view of a structure 104 resulting from a metallization step for depositing a metal material on the structure 103 of FIG. 1D when formed over a bottom electrode layer (not shown). In particularly, a heater metal material such as including, but not limited to: TiN, W, TaN, Al or AlN, is deposited using a chemical vapor deposition (CVD) process or physical vapor deposition (PVD) process. The deposition process results in forming a resulting thin heater metal material layer 89 that conforms to the top surface and sloped sidewall edge surfaces of the patterned dielectric material 65 layer and results in heater electrode or heater filament structures 95 of heater metal material that seamlessly fill in the aligned vertically-oriented circular via openings 76, 86 defined in hard mask and dielectric material patterns 75, 85 respectively.

FIG. 1F shows a close up view of an alternate structure in which a liner material 92 is first deposited in funnel shaped via openings 66 and aligned vertical circular via openings 76, 86 in the structure 103 of FIG. 1D prior to core filling with a heater metal material. That is, as shown in FIG. 1D, as a result of using the tapered RIE, there is achieved a patterned dielectric material layer 65 of surface structures 68 defining funnel-shaped via openings 66 of an aspect ratio that enables a material fill with minimal or no seams. As shown in FIG. 1F, at the sub-EUV dimensions, this defined surface topology of FIG. 1D first enables a PVD of a metal-nitride material liner 89 having a via bottom liner portion 93 of a thickness that is thicker than the sidewall metal-nitride liner portions 94 without seams. In an embodiment, PVD deposition process can deposit a liner 89 of a liner material including, but not limited to: TaN, TiN, AIN, WN, amorphous Carbon (α-C), Cobolt, Ruthenium, etc. As shown in FIG. 1F, the funnel shaped via openings 66 enables deposition of metal-nitride liner and core fill material that avoids pinch-off. A first conducted PVD metal nitride material deposition can provide a continuous layer of thick bottom liner 93 with less sidewall deposition 94 due to straight sidewalls. This resulting structure 90 results in the forming of a heater structure 90 having a thicker TaN liner bottom 93 which improves heat insulation, i.e., blocks heat better. Further, a final PVD deposited metal-nitride heater core fill material 95, e.g., TaN, is absent of any voids/gaps/seams due to the tapered RIE profile and aspect ratio of funnel-shaped openings 66 achieved at patterned dielectric material layer 65.

FIG. 1G shows a cross-sectional view of a stencil structure 105 resulting from a chemical mechanical planarization (CMP) step applied to the structure 104 of FIG. 1E to remove the remaining patterned dielectric material 65 layer and remove the remaining patterned hard mask metal layer 75 to result in a patterned dielectric layer 85 having formed sub-EUV lined metal heater features 95 without voids/seams/gaps. Each formed sub-EUV metal heater structure 95 is of a width l₁ of approximately 8 nm and are spaced apart according to a distance l₂ of approximately 28 nm, e.g., as determined by DCD (LTH)-FCD (SiN) formula. In the non-limiting example, this results in a pitch range of about 32 nm-40 nm range. This resulting patterned dielectric layer 85 of resulting structure 105 including formed sub-EUV lined metal heater features 95 can be a pre-cursor or stencil for further patterning. For example, each of these formed sub-EUV dimensioned lined metal heater structures 95 align with a subsequently formed memory cell, i.e., a phase change memory cell, formed in alignment therewith in subsequent process steps (not shown).

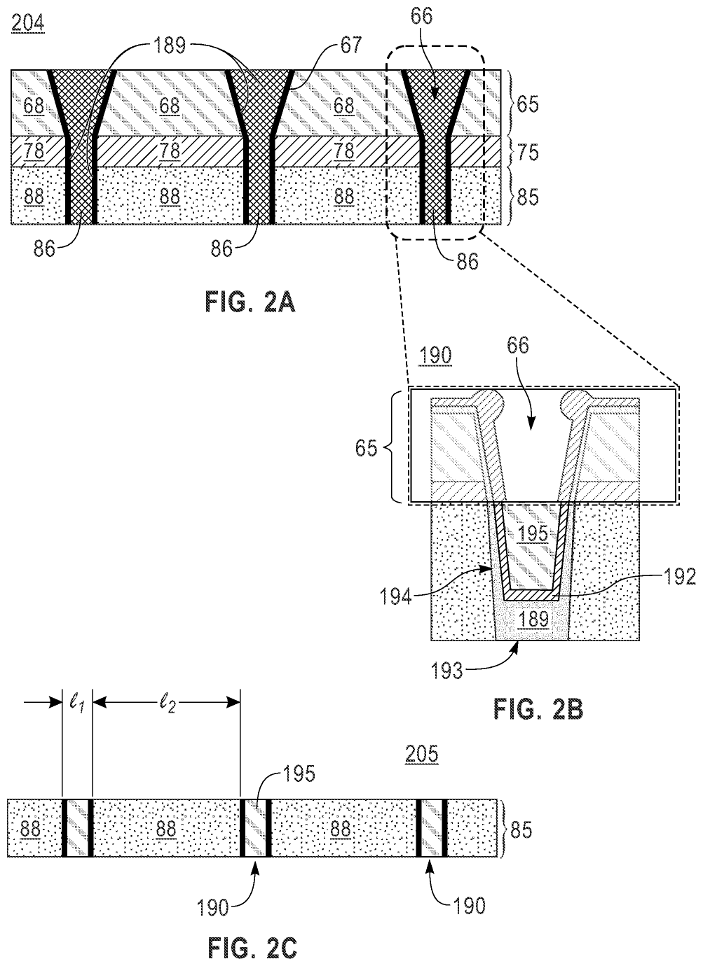

FIGS. 2A-2C depict an alternate embodiment of method steps for manufacturing a PCM memory device in a manner that generates sub-EUV via features according to a further aspect of the present disclosure.

In particular, FIG. 2A shows a further cross-sectional view of a structure 204 of a second embodiment resulting from a metallization step for depositing a metal material liner 189 on the structure 103 of FIG. 1D when formed over a bottom electrode layer (not shown). In particular, a heater metal material such as TiN, W, TaN, Al or AlN is deposited using a CVD or PVD process in a manner that lines the surfaces of the sloped sidewalls 67 of the defined funnel-shaped openings 66 in the patterned dielectric layer 65 and forms a liner at the inside surfaces of the aligned etched holes 76, 86 of respective patterned hard mask 75 and patterned first dielectric layer 85. As in the embodiment of FIG. 1F, the funnel shaped via openings 66 enables deposition of metal-nitride liner and core fill material that avoids pinch-off. The CVD or PVD deposition of metal-nitride liner material results in forming a heater metal material liner 189 of approximately 2-3 nm thick. There is additionally an optional etch bias (e.g., In situ sputter etch bias) and dielectric fill step that can be conducted after forming liner 189. FIG. 2A shows the lined tapered openings 66 in the patterned dielectric layer 65 lined with metal nitride liner material and shows the lined etched circular via holes 76, 86 of respective patterned hard mask layer 75 and patterned dielectric layer 85.

In an alternate embodiment, a resulting structure 190 shown in FIG. 2B depicts a result of depositing a first liner material 189 in funnel shaped via openings 66 and aligned vertical circular via openings 76, 86 in the structure 204 of FIG. 2A, and depositing a core heater metal material 195 in the vertically-oriented circle via openings 86. That is, as a result of using the tapered RIE to form funnel shaped via openings 66 of FIG. 1D, there is achieved a patterned dielectric material layer 65 of surface structures 68 defining funnel-shaped openings 66 of an aspect ratio that enables metal fill with minimal or no seams. At the sub-EUV dimensions, this defined surface topology of FIG. 1D first enables a PVD of a metal material outer liner 189, e.g., TaN, having a continuous thick bottom liner portion 193 of a thickness that is thicker than the sidewall liner portions 194 without seams. Other metal material liners can include TiN, AIN, WN, α-C, etc. As shown in FIG. 2B, the funnel shaped via openings 66 enables deposition of a metal-nitride material liner 189 (e.g., TaN) and a core fill material 195 that avoids pinch-off. A first conducted PVD metal nitride material deposition can provide a continuous outer layer of thick bottom liner 193 with less metal nitride material deposition sidewall deposition 194 due to straight sidewalls. This resulting heater structure 190 has a thicker metal nitride material liner bottom 193 which improves heat insulation, i.e., blocks heat better. A further deposition step of a metal-nitride material such as TiN can result in the formation of a further inner metal-nitride filament layer 192 conforming to the interior surfaces of outer liner portions 193, 194. This filament layer can be a TiN layer deposited by Atomic Layer Deposition (ALD) process. Further, a final PVD deposition step is performed to deposit a metal-nitride core fill material 195, e.g., TaN, that is absent of any voids/gaps/seams due to the tapered RIE profile and aspect ratio achieved of funnel-shaped openings 66 that avoids pinch-off at patterned dielectric material layer 65.

Alternatively, rather than depositing metal-nitride core fill material 195, an interlevel dielectric material fill 195 can be deposited in a final PVD deposition step, e.g., that can include but is not limited to: SiO₂ or SiN, e.g., deposited by ALD/CVD processes.

FIG. 2C shows a cross-sectional view of a resulting stencil structure 205 of the second embodiment resulting from a CMP step applied to the structure 204 of FIG. 2A to remove the remaining patterned dielectric material 65 layer and remove the remaining patterned hard mask metal layer 75 to result in a patterned dielectric layer 85 having formed spaced-apart sub-EUV metal heater structures 190. Each formed sub-EUV metal heater structure 190 includes the circular via opening of a diameter l₁ of approximately 8 nm having a liner 189 and is filled with either a metal-nitride or dielectric material 195. Adjacent sub-EUV metal heater liner structures 190 are spaced apart according to a distance l₂ of approximately 28 nm. In an embodiment, a opening of a diameter l₁ ranges from between 6 nm-10 nm and a distance l₂ can range from between 26 nm 30 nm. This resulting patterned dielectric layer 85 of resulting stencil structure 205 that includes formed sub-EUV metal heater structures 190 can be a pre-cursor or stencil for further patterning. For example, each of these formed sub-EUV dimensioned metal heater structures 190 can align with a memory cell, i.e., a phase change memory cell, formed in alignment therewith in subsequent process steps (not shown).

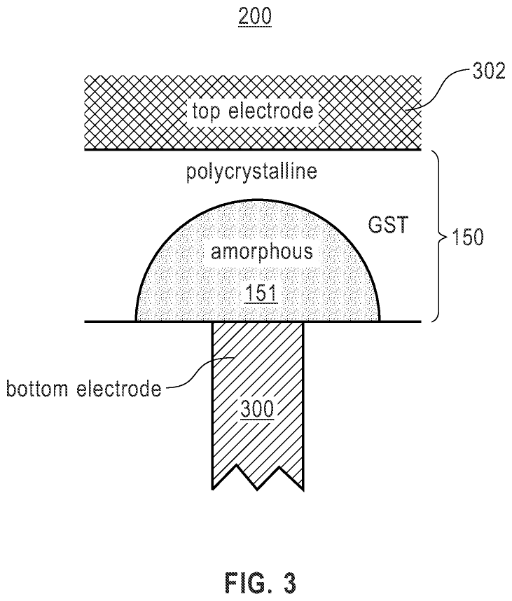

FIG. 3 depicts a memory cell structure 200 having a bottom heater electrode structure 300 formed in accordance with the embodiments described herein. For example, in one embodiment a PCM mushroom-cell memory element 150 including an active volume of Ge₂Sb₂Te₅ (GST) material formed on a respective sub-EUV dimensioned heater metal filament of the stencil structure 105 of FIG. 1(G. In another design, a PCM mushroom-cell memory element 150 including the active volume of GST material is formed on a respective sub-EUV dimensioned heater filament of the stencil structure 205 of FIG. 2B.

That is, as shown in FIG. 3, a PCM cell memory element 150 is formed to electrically contact an aligned lithographically-defined bottom heater metal electrode 300, whether consisting of the sub-EUV dimensioned bottom heater metal filament structure 95 such as shown in FIG. 1G, or the sub-EUV dimensioned metal heater liner features 190 such as shown in FIG. 2B. Electrical connection is shown between a corresponding aligned active amorphous GST (α-GST) phase change material portion 151 of memory element 150. The defined dimension of sub-EUV dimensioned bottom heater metal filament structure 95 such as shown in FIG. 1G or the sub-EUV metal heater liner features 190 such as shown in FIG. 2B determines the size of the switching volume of the α-GST material portions 151 of cell 150. The sub-EUV dimensioned bottom heater electrode 300 causes PCM cell 200 to undergo amorphous to crystalline state transformations as a function of the voltage and current applied to the bottom electrode 300.

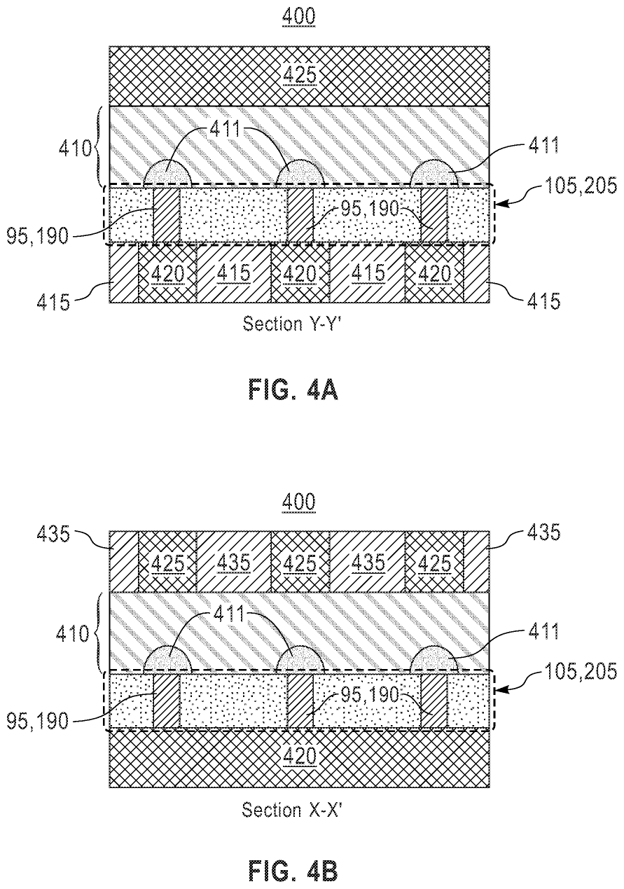

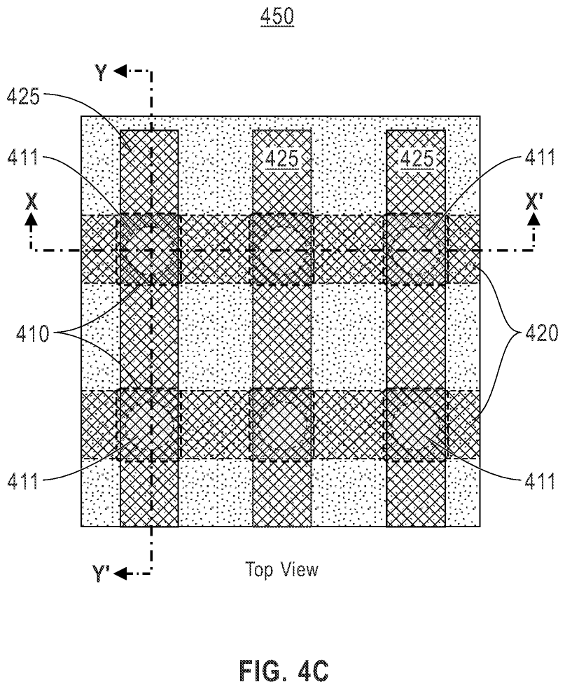

FIGS. 4A-4C represent various views of a 2-D or 3-D PCM cell memory array including a stencil structure having sub-EUV dimensioned bottom lined heater metal structures according to an embodiment herein.

In particular, FIGS. 4A-4C represent various views of a 2-D or 3-D PCM cell memory array 400 including either a stencil structure 105 having sub-EUV dimensioned bottom lined heater metal structures 95 such as shown in FIG. 1F, or the stencil structure 205 having sub-EUV dimensioned lined heater metal structures 190 such as shown in FIG. 2B.

FIG. 4A shows a cross-sectional view of a 2-D or a 3-D PCM cell memory array 400 having a series of multiple memory elements 410 formed on a formed stencil, i.e., a dielectric layer stencil 105 having sub-EUV dimensioned bottom heater metal filaments 95 shown in FIG. 1G, or stencil 205 having sub-EUV dimensioned metal heater liner features 190 such as shown in FIG. 2B. As shown in FIG. 4A, in alignment with a respective bottom heater metal filament 95 or metal heater liner feature 190, is a respective PCM mushroom-cell memory element 410 each cell having a GST material, e.g., crystalline GST or c-GST, and corresponding α-GST switching material portion 411. As shown in FIG. 4A, in an embodiment, the memory cell array 400 is formed on an interlevel low-k dielectric (ILD) or Tetraethyl orthosilicate (TEOS) material layer 415 having a surface over which is formed either the dielectric layer stencil 105 having sub-EUV dimensioned bottom heater metal filaments 95 shown in FIG. 1G, or stencil 205 having sub-EUV dimensioned metal heater liner features 190 such as shown in FIG. 213. Formed in a patterned TEOS material layer 415 are respective metal conductors (metal line or wire) 420 each metal conductor 420 electrically connected to a respective individual sub-EUV dimensioned bottom heater metal filament 95 shown in FIG. 1G, or alternatively connected to a respective individual sub-EUV dimensioned metal heater liner features 190 such as shown in FIG. 2B. In embodiments, an individual metal conductor line or wire 420 receives a voltage or current signal used for programming a resistive state of an individual PCM memory cell 410. As further shown in FIG. 4A, each PCM memory cell electrically connects to a single top metal electrode 425 that is formed in an interlevel dielectric layer above and that is in alignment with the line or memory cells 410 for electrical connection to each cell 410.

In an embodiment, each line or wire is formed of a metal material such as copper, tungsten, copper alloy, cobalt, or any suitable conducting metals and can be lined with a barrier layer, e.g., Ta, TaN, Ti, TiN or any suitable liner material (not shown).

FIG. 4B depicts a cross-sectional view of the 2-D or 3-D PCM cell memory array 400 of FIG. 4A however showing the array structure rotated 90 degrees. The cross-sectional view of the 90°-rotated 2-D or 3-D PCM cell memory array structure of FIG. 4B depicts a series of memory elements 410, with each memory cell element having a corresponding respective aligned top electrode 425 formed in a top interlevel dielectric layer 435 of dielectric material. e.g., TEOS. The cross-sectional view of the rotated 2-D or 3-D PCM cell memory array structure of FIG. 4B further depicts a series of memory elements 410 in the rotated orientation that electrically connect to a single individual metal conductor line or wire 420 receives a voltage or current signal for programming an individual memory cell 410. Although not shown, an exemplary current flow applied from the bottom individual metal conductor line or wire 420 through either the sub-EUV dimensioned bottom heater metal filament 95 of stencil 105 sub-EUV dimensioned metal heater liner features 190 and through respective memory cell element that can be read or sensed via the top metal electrode 425.

FIG. 4C depicts a top-down view 450 of the 2-D or 3-D PCM cell cross-bar memory array 400 of FIGS. 4A and 4B depicting the linear series of PCM memory cells 410 formed on either the stencil 105 having sub-EUV dimensioned bottom heater metal filaments 95 shown in FIG. 1G, or stencil 205 having sub-EUV dimensioned metal heater liner features 190 such as shown in FIG. 2C. FIG. 4A in particular shows the cross-sectional view of the structure 450 of FIG. 4C taken along line Y-Y′ with the linear series of cells 410 of the 2D array connected to a respective top conductor 425. FIG. 4B shows the cross-sectional view of the structure 450 of FIG. 4C taken along line X-X′ with the linear series of cells 410 of the 2D array connected to a respective bottom metal conductor 420.

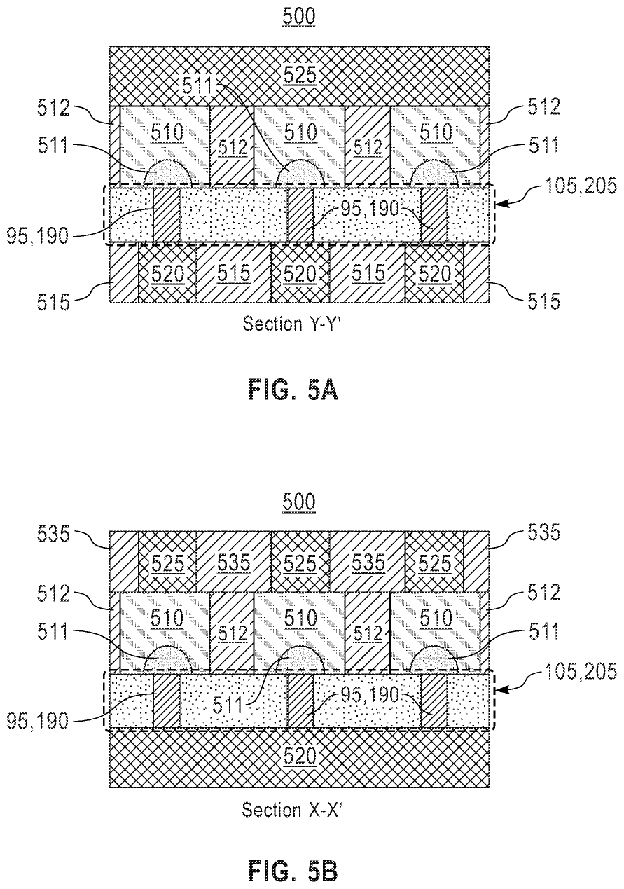

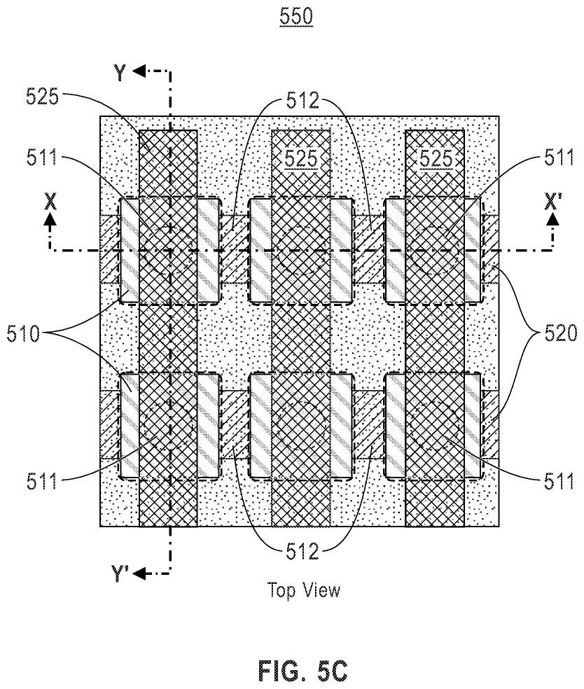

FIGS. 5A-5C represent various views of a 2-D or 3-D PCM cell memory array of a further embodiment that includes PCM memory cells formed on a stencil structure having sub-EUV dimensioned bottom heater metal structures according to a further embodiment.

In particular, FIGS. 5A-5C represent various views of a 2-D or 3-D PCM cell memory array 500 of a further embodiment that includes PCM memory cells formed on either a stencil structure 105 having sub-EUV dimensioned bottom heater metal filament structures 95 such as shown in FIG. 1G, or the stencil structure 205 having sub-EUV dimensioned metal heater liner features 190 such as shown in FIG. 2C.

FIG. 5A shows a cross-sectional view of a 2-D or 3-D PCM cell memory array 500 having a series of multiple individual memory elements 410 formed on a formed stencil, i.e., a dielectric layer stencil 105 having sub-EUV dimensioned bottom heater metal filaments 95 shown in FIG. 1G, or stencil 205 having sub-EUV dimensioned metal heater liner features 190 such as shown in FIG. 2C. The difference between the memory cell array 500 of FIG. 5A versus the memory cell array 400 embodiment of FIG. 4A is that each PCM memory cell in the embodiment of the PCM cell memory array 500 of FIG. 5A is isolated and separated from an adjacent PCM memory cell 510 by a dielectric material spacer 512. That is, in an embodiment, during the manufacture of the PCM memory cell elements 510 is the formation of spacers between each memory cell, each spacer comprising SiO₂ or like dielectric material spacer fill 512.

As shown in FIG. 5A, in alignment with a respective bottom heater metal filament 95 or metal heater liner feature 190, is a respective PCM mushroom-cell memory element 510 each cell having a GST material (e.g., Poly-GST or c-GST) and corresponding α-GST switching material portion 511. As shown in FIG. 5A, in an embodiment, the memory cell array 500 is formed on an interlevel low-k dielectric (ILD) or Tetraethyl orthosilicate (TEOS) material layer 515 having a surface over which is formed either the dielectric layer stencil 105 having sub-EUV dimensioned bottom heater metal filaments 95 shown in FIG. 1G, or stencil 205 having sub-EUV dimensioned metal heater liner features 190 such as shown in FIG. 2C. Formed in a patterned TEOS material layer 515 are respective metal conductors (metal line or wire) 520 each metal conductor 520 electrically connected to a respective individual sub-EUV dimensioned bottom heater metal filament 95 shown in FIG. 1G, or alternatively connected to a respective individual sub-EUV dimensioned metal heater liner features 190 such as shown in FIG. 2C. In embodiments, an individual metal conductor line or wire 520 receives a voltage or current signal used for programming a resistive state of an individual PCM memory cell 510. As further shown in FIG. 5A, each PCM memory cell electrically connects to a single top metal electrode 525 that is formed in an interlevel dielectric layer above and that is in alignment with the line or memory cells 510 for electrical connection to each cell 510.

In an embodiment, each line or wire is formed of a metal material such as copper, tungsten, copper alloy, cobalt, or any suitable conducting metals and can be lined with a barrier layer, e.g., Ta, TaN, Ti, TiN or any suitable liner material (not shown).

FIG. 5B depicts a cross-sectional view of the 2-D or 3-D PCM cell memory array 500 of FIG. 5A however showing the array structure rotated 90 degrees. The cross-sectional view of the 90°-rotated 2-D or 3-D PCM cell memory array structure of FIG. 5B depicts a series of individual and isolated memory elements 510 separated by spacers 512, with each memory cell element having a corresponding respective aligned top electrode 525 formed in a top interlevel dielectric layer 535 of dielectric material, e.g., TEOS. The cross-sectional view of the rotated 2-D or 3-D PCM cell memory array structure of FIG. 5B further depicts a series of memory elements 510 in the rotated orientation that electrically connect to a single individual metal conductor line or wire 520 receives a voltage or current signal for programming an individual memory cell 510. Although not shown, an exemplary current flow applied from the bottom individual metal conductor line or wire 520 through either the sub-EUV dimensioned bottom heater metal filament 95 of stencil 105 sub-EUV dimensioned metal heater liner features 190 and through respective memory cell element that can be read or sensed via the top metal electrode 525.

FIG. 5C depicts a top-down view 550 of the 2-D or 3-D PCM cell cross-bar memory array 500 of FIGS. 5A and 5B depicting a linear series of individual and isolated PCM memory cells 510, each cell separated by dielectric material spacer 512, formed on either the stencil 105 having sub-EUV dimensioned bottom heater metal filaments 95 shown in FIG. 1G, or stencil 205 having sub-EUV dimensioned metal heater liner features 190 such as shown in FIG. 2C. FIG. 5A in particular shows the cross-sectional view of the structure 550 of FIG. 5C taken along line Y-Y′ with the linear series of cells 510 of the 2D array connected to a respective top conductor 525. FIG. 5B shows the cross-sectional view of the structure 550 of FIG. 5C taken along line X-X′ with the linear series of cells 510 of the 2D array connected to a respective bottom metal conductor 520.

The methods of FIGS. 1A-1G and 2A-2C propose a new integration and patterning approach to enable PCM cell sub-EUV bottom electrode heaters that can be metallized simply with CVD metals and metal nitrides for high resistance/low power switching and reduced amorphous volumes. That is, EUV lithography processes and etch bias it Utilized to further shrink the via size whilst enabling a large top CD aperture to enable metallization with PVD/ALD. These methods enable a more vertical heater via size wall. Further embodiments include a multi-mushroom cross-bar like PCM cell array enabled by sub-EUV heaters. By minimizing the heater dimension, the PCM cell amorphous switching volume is minimized and provides for undamaged GST volumes, reduces current draw (operates at lower power) and improves device density. The smaller heater sizes leads to more efficient PCM device performance.

The methods of FIGS. 1A-IG and 2A-2C can be applied to PCM device technology at the heater module and the method is scalable to enable higher density PCM architectures.

While the disclosure has been described in terms of specific embodiments, it is evident in view of the foregoing description that numerous alternatives, modifications and variations will be apparent to those skilled in the art. Various embodiments of the present disclosure can be employed either alone or in combination with any other embodiment, unless expressly stated otherwise or otherwise clearly incompatible among one another. Accordingly, the disclosure is intended to encompass all such alternatives, modifications and variations which fall within the scope and spirit of the disclosure and the following claims.

What is claimed is:

1. A phase change material (PCM) memory cell comprising:
a bottom electrode of a metal-containing material;
a memory cell structure comprising a phase change material; and
a metal heater element of sub-extreme ultraviolet (sub-EUV) dimension situated between and electrically connecting the bottom electrode and PCM memory cell structure, the metal heater element comprising a vertical circular via structure of sub-EUV dimension having a seamless fill material.

2. The PCM memory cell of claim 1, wherein the seamless fill material comprises a metal-nitride fill material.

3. The PCM memory cell of claim 2, wherein the vertical circular via structure of sub-extreme ultraviolet (sub-EUV) dimension further comprises a metal-nitride liner of sub-EUV dimension.

4. The PCM memory cell of claim 3, wherein the metal-nitride liner of sub-EUV dimension includes a thicker metal-nitride liner bottom surface portion and thinner sidewall metal-nitride portions.

5. The PCM memory cell of claim 1, wherein the metal heater element comprising a vertical circular via structure of sub-EUV dimension includes an outer metal-nitride liner of a first metal-nitride material and an inner metal-nitride filament layer of a second metal-nitride material.

6. The PCM memory cell of claim 5, wherein the outer metal-nitride liner of sub-EUV dimension includes a thicker metal-nitride liner bottom surface portion and thinner sidewall metal-nitride portions.

7. The PCM memory cell of claim 6, wherein the seamless fill material comprises a material selected from: a metal-nitride fill material, or a dielectric fill material.

8. The PCM memory cell of claim 1, wherein said metal heater element via structure of sub-EUV dimension is formed in a first dielectric material layer directly underlying the PCM memory cell structure, said bottom electrode formed in a second dielectric layer underlying said first dielectric material layer.

9. A phase change material (PCM) memory cell array comprising:
a first insulative material layer comprising a plurality of bottom electrodes of a metal-containing material;
a plurality of memory cell structures of phase change material, each memory cell structure in alignment with a respective bottom electrode; and
a plurality of metal heater elements of sub-extreme ultraviolet (sub-EUV) dimension, a respective metal heater element situated between and electrically connecting a respective bottom electrode and a respective PCM memory cell structure, each respective metal heater element comprising a vertical circular via structure of sub-EUV dimension having a seamless fill material.

10. The PCM memory cell array of claim 9, wherein the seamless fill material comprises a metal-nitride fill material.

11. The PCM memory cell array of claim 10, wherein the vertical circular via structure of sub-extreme ultraviolet (sub-EUV) dimension further comprises a metal-nitride liner of sub-EUV dimension.

12. The PCM memory cell array of claim 11, wherein the metal-nitride liner of sub-EUV dimension includes a thicker metal-nitride liner bottom surface portion and thinner sidewall metal-nitride portions.

13. The PCM memory cell array of claim 9, wherein each metal heater element comprising a vertical circular via structure of sub-EUV dimension includes an outer metal-nitride liner of a first metal-nitride material and an inner metal-nitride filament layer of a second metal-nitride material.

14. The PCM memory cell array of claim 13, wherein the outer metal-nitride liner of sub-EUV dimension includes a thicker metal-nitride liner bottom surface portion and thinner sidewall metal-nitride portions.

15. The PCM memory cell array of claim 14, wherein the seamless fill material comprises a material selected from: a metal-nitride fill material, or a dielectric fill material.

16. The PCM memory cell array of claim 9, wherein said plurality of metal heater elements of sub-EUV dimension are formed in a first dielectric material layer directly underlying the PCM memory cell structures, said plurality of bottom electrodes formed in a second dielectric layer underlying said first dielectric material layer.

17. A method of forming a phase-change material (PCM) memory cell comprising:
forming a first insulating material layer having a bottom electrode of a metal-containing material;
forming a second insulating material layer having a metal heater element of sub-extreme ultraviolet (sub-EUV) dimension, said metal heater element of sub-EUV dimension comprising a vertical circular via structure of sub-EUV dimension in alignment with and electrically connecting the bottom electrode, said vertical circular via structure having a seamless fill material; and
forming a PCM memory cell structure above and electrically connecting the metal heater element of sub-EUV dimension.

18. The method of claim 17, wherein said forming the second insulating material layer having a metal heater element of sub-EUV dimension comprises:
forming the second insulating material layer above the first insulating material layer;
forming a hard mask dielectric material layer above said second insulating material layer;
forming an intermediate dielectric material layer above said hard mask dielectric material layer;
etching said intermediate dielectric material layer using a tapered etch process to achieve a topographic profile defining one or more funnel shaped openings;
performing a further etch process within a defined funnel shaped opening to form a circular via opening aligned with said funnel shaped opening and extending through said hard mask dielectric material layer and said second insulating material layer;
perform a vapor deposition process to seamlessly deposit said fill material in said vertical circular via opening; and
removing said intermediate dielectric material layer and removing said hard mask dielectric material layer.

19. The method of claim 18, wherein said seamlessly deposited fill material in said vertical circular via opening comprises a metal-nitride fill material.

20. The method of claim 19, wherein prior to performing a vapor deposition process to seamlessly deposit said fill material, a further step of:
depositing a metal-nitride liner of sub-EUV dimension within said vertical circular via opening, the metal-nitride liner of sub-EUV dimension including a thicker metal-nitride liner bottom surface portion and thinner sidewall metal-nitride portions.
